(19) United States
(12) Patent Application Publication
(10) Pub. No.: US 2009/0206397 A1
(43) Pub. Date: Aug. 20, 2009

(54) Lateral Trench MOSFET with Conformal Depletion-Assist Layer

(75) Inventor: Donald Ray Disney, Cupertino, CA (US)

Correspondence Address: ADVANCED ANALOGIC TECHNOLOGIES, 3230 Scott Blvd, Santa Clara, CA, 95054, US

(73) Assignee: ADVANCED ANALOGIC TECHNOLOGIES, INC., Sunnyvale, CA (US)

(21) Appl. No.: 12/032,289

(22) Filed: Feb. 15, 2008

(51) Int. Cl. H01L 29/78

(52) U.S. Cl. 257/330; 257/E29.257

(57) ABSTRACT

A lateral trench DMOS device formed in a substrate of a first conductivity type includes a vertical trench lined with a dielectric layer and containing a gate electrode. A source region of a second conductivity is adjacent the surface of the substrate and a sidewall of the trench. A drain region of the second conductivity type is adjacent the surface of the substrate and spaced apart from the source region. A field oxide region is disposed at the surface of the substrate between the source region and the drain region and a drift region of the second conductivity type extends laterally from the trench sidewall to the drain region. A body region of a first conductivity type is disposed between the source region and the drift region, the body region adjacent the trench sidewall where the body region has a profile that is conformal to the field oxide region.

### BACKGROUND OF THE INVENTION

Lateral Trench MOSFET (LTDMOS) devices are power semiconductor devices that may be integrated with control circuitry to form monolithic power integrated circuits (ICs) used in a wide range of applications, including power management ICs. LTDMOS devices consist of large trench areas that are oxidized and filled with polysilicon (poly). The poly forms the gate electrode of the LTDMOS, the oxide layer forms the gate oxide, and channel regions are formed on the sidewalls of the silicon trenches. Current generally flows vertically through the channel regions, then laterally through a drift region.

Prior art LTDMOS devices have limited breakdown voltage capability and on-state performance due to the configuration of their drift regions, which depend on the reverse-biased junction with the substrate, and possibly an overlying field plate, to deplete them in the off-state. This limits the maximum drift region charge, which directly increases the on-resistance of these devices.

Therefore, a goal of this invention is to provide improved LTDMOS devices that are capable of higher breakdown voltages and/or lower on-state resistances than prior art devices.

### SUMMARY OF THE INVENTION

An embodiment of the present invention provides a lateral trench MOFSFET (LTDMOS) device having a higher breakdown voltages and/or lower on-state resistances than prior art devices. For a typical embodiment, an LTDMOS device is fabricated in a P-type semiconductor substrate. A gate is formed by etching a trench in the substrate, depositing a gate dielectric layer on the sidewalls of the trench and refilling the trench with a conductive gate. A field oxide region is formed on the surface of the substrate. The field oxide region is formed to leave unmasked regions (regions where the field oxide region is thin or non-existent) on either side. The first of these unmasked regions is located between the field oxide region and the sidewall of the trench while the second is positioned on the side of the field oxide region that is more distant from the trench sidewall.

An N-type drift region is formed in the substrate by high-energy implantation through the field oxide region. The drift region has a profile that is conformal to the thickness of the field oxide region. This means that the drift region is thickest in the unmasked regions and thinnest under the field oxide region.

A P-body region is formed in the drift region by high-energy implantation. The P-body region is formed under the first unmasked region (i.e., adjacent to the gate dielectric) and extend some distance under the field oxide region. In a preferred embodiment, the P-body is formed by multiple implants at different implantation energies. The portion of the P-body region that extends under the field oxide region has a different depth and dopant profile than the portion of the P-body region is implanted into the first unmasked region and serves as a depletion-assist layer. Together with the P-substrate, the portion of the P-body region that extends under the field oxide region depletes the drift region to help support high voltage in the off-state.

### BRIEF DESCRIPTION OF THE DRAWINGS

FIG. 1 is a cross-section of a prior art LTDMOS device.

FIG. 2 is a cross-section of an LTDMOS device according to an embodiment of the present invention with conformal depletion-assist layer.

FIG. 3 is a graph showing doping profiles of the drift region and depletion-assist layers in the new LTDMOS device.

### DETAILED DESCRIPTION OF THE PREFERRED EMBODIMENTS

FIG. 1 shows a prior art Lateral Trench MOSFET (LTDMOS) from U.S. patent application Ser. No. 11/982,764 entitled “High-Voltage Bipolar-CMOS-DMOS Integrated Circuit Devices and Modular Methods of Forming the Same”, which is incorporated herein by reference. This LTDMOS is formed in a P-type semiconductor substrate 101. The gate 108 of the LTDMOS is formed by etching a trench in the substrate 101, forming a gate dielectric layer 107 on the sidewalls of the trench, and refilling the trench with a conductive gate 108. In a preferred embodiment, the gate dielectric 107 comprises a thermal silicon dioxide layer with thickness in the range of 100 to 500 angstroms, and the gate 108 comprises heavily-doped polysilicon. A field oxide region 109 is formed on the surface of substrate 101. N-type drift region 102 is formed by high-energy implantation through field oxide 109, forming a profile that is conformal to the thickness of the field oxide 109 (i.e. the portion of drift region 102 implanted through field oxide 109 is shallower than the portion of drift region 102 that is implanted directly into substrate 101). P-body region 103 is formed adjacent gate dielectric 107, preferably by high-energy implantation at multiple energies to tailor the doping profile to achieve the desired LTDMOS electrical characteristics, such as threshold voltage and prevention of punch-through. In this prior art example, P-body region 103 is implanted at an energy that is low enough such that the implant is essentially blocked by field oxide 109. Heavily-doped N+drain region 104 is formed in drift region 102 and separated from P-body 103 by field oxide 109. Heavily-doped N+ source region 105 is formed in P-body 103 adjacent gate dielectric 105. Heavily-doped P+ body contact region 106 is formed in P-body 103 to provide ohmic contact to the P-body region and to prevent activation of the NPN parasitic transistor formed by drift region 102, P-body region 103, and source region 105. Interlevel dielectric (ILD) 110 covers the LTDMOS and has contact holes that allow topside contact by drain electrode 111 and source/body electrode 112.

In the off-state, drift region 102 is depleted by reverse biased junctions with P-body 103 and substrate 101. The influence of the drift region depletion from the P-body junction is limited only the portion of the drift region nearest the P-body junction. The remainder of the drift region must be depleted by the substrate junction. To obtain full depletion of the drift region, the total charge in the drift region must be low enough to be successfully depleted by the substrate without encountering an electric field that exceeds the critical level that leads to avalanche breakdown. Limiting the total charge in the drift region directly increases the on-resistance of the LTDMOS, making it less area efficient and, thus, more costly. Moreover, because it is difficult to control the doping of the substrate (i.e. it has process variation on the order of ±20%), the LTDMOS BV is subject to large process variations.

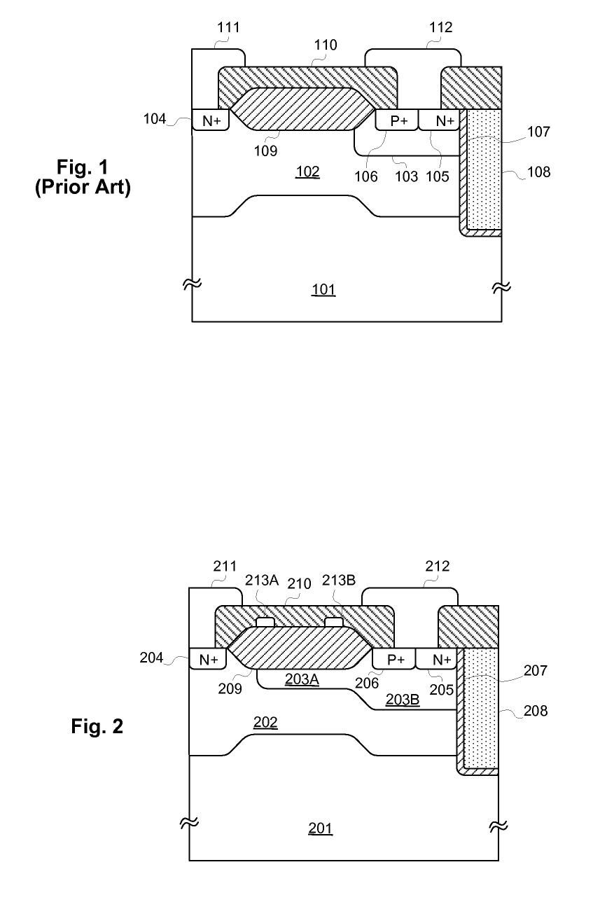

FIG. 2 shows the schematic cross-section of an LTDMOS according to one embodiment of the present invention. This structure is similar to the prior art LTDMOS of FIG. 1 in many respects, including semiconductor substrate 201, trench gate 208, gate dielectric layer 207, field oxide 209, drift region 202 that is conformal to the thickness of the field oxide 209, N+ drain region 204, N+ source region 205, P+ body contact region 206, ILD 210 drain electrode 211 and source/body electrode 212. In this device, however, at least a portion of the P-body region 203 is implanted at a high energy such that it penetrates field oxide region 209. In a preferred embodiment, the P-body is formed by multiple implants at different implantation energies. The portion of P-body 203A that is implanted through field oxide 209 has a different depth and dopant profile than the portion 203B that is implanted into the surface of the substrate or through a much thinner screen oxide. The P-body region 203A serves as a depletion-assist layer. Together with the P-substrate, region 203A depletes the drift region 202 to help support high voltage in the off-state. This is the so-called Reduced Surface Field (RESURF) effect, as described in “A Review of RESURF Technology,” A. Ludikhuize, Proceeding of International Symposium on Power Semiconductor Devices and ICs, 2000, pp. 11-18. The P-body region 203B also serves to deplete a portion of drift region 202. Optional field plate regions 213A and 213B may be formed above portions of the drift region to further reduce surface electric fields.

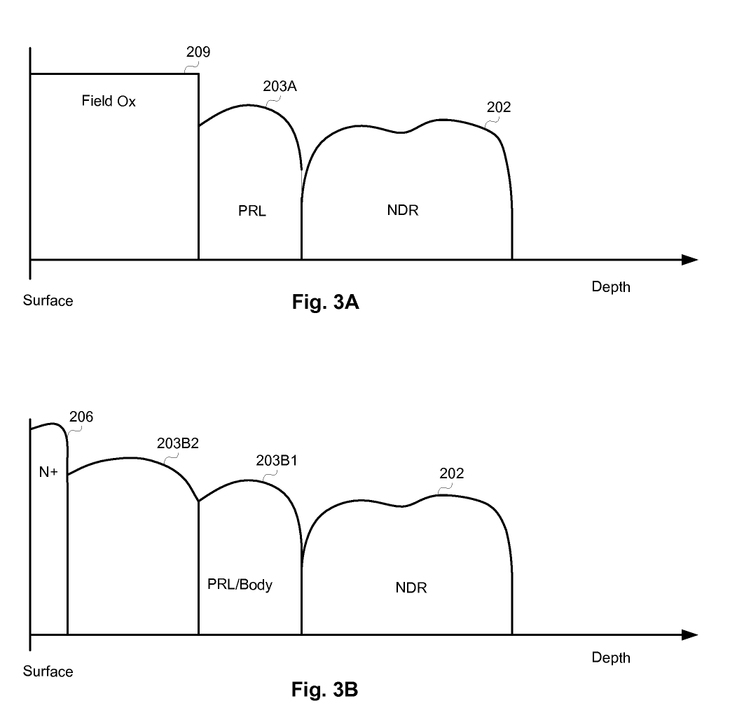

FIGS. 3A and 3B show graphical representation of the doping profile of the P-body, N-drift, and substrate regions. The x-axes in these Figures show the depth in the silicon, while the y-axes show the doping concentration (i.e. atoms/cm3) of each region (not to scale). FIG. 3A shows the regions in the field oxide area, while FIG. 3B shows the area under the source and body contact regions of FIG. 2. The N-type drift region profile in this preferred embodiment is essentially the same in both areas, since it is implanted at high enough energy to completely penetrate the field oxide. As shown in this example, the N-drift implant comprises two implantations at different energies to create a relatively flat doping profile with a greater thickness than would be possible using a single implant. The energies of these drift implants are preferably in the range of 800 keV to 1200 keV and 1200 keV to 2000 keV, respectively, to provide a bottom junction depth in the range of 1 to 2 microns. The total charge in the drift region is approximately the sum of the doses used for each of the individual implants. For optimum device BV and Rsp performance, the total drift region charge is preferably in the range of 1E12-3E12 atoms/cm2.

FIG. 3B shows one embodiment of a P-body region implanted directly into the silicon surface, or alternatively through a layer that is substantially thinner than field oxide 209. In this example, the P-body implant 203B comprises two implantations at two different energies, with doping profiles 203B1 and 203B2. FIG. 3A shows that at least a portion 203A of the P-body implant 203B1 penetrates the field oxide 209 to form a depletion-assist layer between field oxide 209 and drift region 202. The shallower implant 203B2 is completely blocked by field oxide 209, such that it does not contribute substantially to the dopant profile in the silicon. Region 203A may be substantially the same as 203B1 or may be just a portion of this region. In other embodiments, the P-body implant may comprise more than two impants at different energies, and upper portion of one or more of these implants will be blocked by the field oxide, such that the P-body dose under field oxide 209 is lower than the P-body dose under the source region.

In a preferred embodiment, the energies of the first and second P-body implants are in the range of 200 to 300 keV and 300 keV to 900 keV to provide a bottom junction depth in the range of 0.5 to 1.5 microns. The total charge in the P-body region 203A is preferably in the range of 0.5-1.5E12, in order to achieve the optimum depletion-assist function. The total charge in P-body region 203B may be significantly higher than the charge in 203A without affecting the depletion-assist function. The total charge and doping concentration profile in 203B should be optimized to set the desired threshold voltage and to prevent punch-through from the drift region to the N+ source region 205.

What is claimed is:

1. A lateral trench DMOS device formed in a semiconductor substrate of a first conductivity type and comprising:
a trench extending downward from a surface of the substrate, the trench being lined with a dielectric layer and containing a gate electrode;
a source region of a second conductivity type opposite the first conductivity type adjacent the surface of the substrate and a sidewall of the trench;
a drain region of the second conductivity type adjacent the surface of the substrate and spaced apart from the source region;
a field oxide region disposed at the surface of the substrate between the source region and the drain region;
a drift region of the second conductivity type extending laterally from the sidewall of the trench to the drain region; and
a body region of a first conductivity type disposed between the source region and the drift region, the body region adjacent the sidewall of the trench where the body region has a profile that is conformal to the field oxide region.

2. The lateral trench DMOS device of claim 1 wherein the substrate does not include an epitaxial layer.

3. The lateral trench DMOS device of claim 1 wherein the drift region has a profile that is conformal to the field oxide region.

4. The lateral trench DMOS device of claim 1 wherein the body region has a first body charge in a first area under the field oxide region that is substantially lower than a second body charge in a second area that is not under the field oxide region.

5. The lateral trench DMOS device of claim 1 wherein the drift region has a drift charge that is substantially the same in the first and second areas.

6. The lateral trench DMOS device of claim 1 further comprising a source field plate overlying a portion of the drift region near the source region.

7. The lateral trench DMOS device of claim 1 further comprising a drain field plate overlying a portion of the drift region near the drain region.

8. The lateral trench DMOS device of claim 1 wherein the body region is formed by a plurality of ion implantation steps, with each implantation step performed at a respective implantation energy.

9. The lateral trench DMOS device of claim 1 wherein the drift region is formed by a plurality of ion implantation steps, each implantation step performed at a different implantation energy.

10. The lateral trench DMOS device of claim 5 wherein the drift charge is between 1E12 and 3E12 cm−2.

11. The lateral trench DMOS device of claim 4 wherein the first body charge is between 0.5E12 and 1.5E12 cm−2.

12. The lateral trench DMOS device of claim 8 wherein the highest energy implant penetrates the field oxide region to form a depletion-assist layer between the drift region and the field oxide region.
